(19) United States
(12) Patent Application Publication
(10) Pub. No.: US 2019/0259675 A1
(43) Pub. Date: Aug. 22, 2019

(54) GLASS FRAME FAN OUT PACKAGING AND METHOD OF MANUFACTURING THEREOF

(71) Applicant: DiDrew Technology (BVI) Limited, Santa Clara, CA (US)

(72) Inventors: Minghao Shen, Santa Clara, CA (US); Xiaoming Du, Santa Clara, CA (US)

(73) Assignee: DiDrew Technology (BVI) Limited, Santa Clara, CA (US)

(21) Appl. No.: 15/934,700

(22) Filed: Mar. 23, 2018

Related U.S. Application Data
(60) Provisional application No. 62/632,162, filed on Feb. 19, 2018.

(51) Int. Cl. H01L 23/08; H01L 21/56; H01L 21/48; H01L 21/78; H01L 21/52; H01L 23/498; H01L 23/31

(52) U.S. Cl. CPC H01L 23/08; H01L 21/561; H01L 21/568; H01L 23/3128; H01L 21/78; H01L 21/52; H01L 23/49822; H01L 21/4857

(57) ABSTRACT

Disclosed is a method of manufacturing a semiconductor device that includes a semiconductor die surrounded by a support frame for strengthening the semiconductor device compared to prior devices. A framing member is adhered to a carrier substrate along with dies that are positioned within through-holes in the framing member. The framing member and dies are encapsulated within a molding compound. The carrier substrate is then removed, and an RDL is formed on the dies. The resulting structure is then diced along portions of the framing structure into individual semiconductor devices, leaving portions of the framing structure in place and surrounding the dies as support frames.

### RELATED APPLICATION

The present application claims priority to U.S. Provisional Application No. 62/632,162 filed Feb. 19, 2018, entitled “Glass Frame Fan Out Packaging” of which is incorporated herein by reference in its entirety.

### FIELD OF THE INVENTION

The present disclosure relates to semiconductor packaging technologies.

### BACKGROUND

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays.

Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation.

The terms “die”, “semiconductor chip”, and “semiconductor die” are used interchangeably throughout this specification. The term wafer is used herein include any structure having an exposed surface onto which a layer is deposited according to the present invention, for example, to form the circuit structure.

Advancements in the semiconductor manufacturing technology lead to smaller microelectronic components and circuitry within such components that is increasingly dense. To reduce the dimensions of such components, the structures by which these components are packages and assembled with circuit boards must become more compact. One approach to adopting such technology involves the use of fan-out wafer-level packaging (FOWLP), which is a packaging process in which contacts of a semiconductor die are redistributed over a larger area through a redistribution layer (RDL).

For example, FIG. 1 shows a schematic, cross-sectional diagram of a typical FOWLP wafer level package 100. As shown, a semiconductor die 102 is encapsulated in a mold compound 104. The die 102 may include a plurality of semiconductor device structures (not shown) formed according to known processes. An RDL 106 is formed over the surface of the mold 104 and die 102, and subsequently ball grid array (BGA) balls 108 are formed over the RDL 106. The RDL 106 and BGA 108 allow for electrical communication between the die 102 and external circuitry having a looser footprint. Such redistribution typically includes thin film polymers such as BCB, PI or other organic polymers and metallization such as Al or Cu to reroute the peripheral pads to an area array configuration.

In wafer level packaging, the wafer and the dies are susceptible to warping due to coefficient of thermal expansion (CTE) mismatch. It is known that wafer warpage continues to be a concern. Warpage can prevent successful assembly of a die-to-wafer stack because of the inability to maintain the coupling of the die and wafer. Warpage issue is serious especially in a large sized wafer, and has raised an obstacle to a wafer level semiconductor packaging process that requires fine-pitch RDL process.

The present disclosure provides novel improved packaging methods resulting in reduced warpage or other defects.

### BRIEF SUMMARY

A method of manufacturing a semiconductor device according to the present disclosure include adhering a framing member to a supporting surface of a carrier substrate, where the framing member comprises a plurality of framing structures that define a plurality of through-holes through the framing member. Then a plurality of dies are adhered to the supporting surface of the carrier substrate within respective through-holes of the framing member such that each die has a respective active surface and at least one respective integrated circuit region. Next, the framing member and the plurality of dies are encapsulated within a molding compound. A redistribution layer (RDL) is then formed on the dies, and the resulting structure is diced along portions of the framing structure into individual semiconductor devices. The resulting devices include dies surrounded by portions of the framing structures. The framing structures then serve as a support frame for the die in each device, thereby strengthening the resulting semiconductor device compared to prior devices that lack such a support frame.

In some embodiments, the carrier substrate and/or the framing member can have a coefficient of thermal expansion (CTE) that substantially matches a CTE of the plurality of dies.

In one embodiment, a semiconductor device includes a die having an active surface and at least one integrated circuit region; a framing structure adjacent to the die; an encapsulant at least partially encapsulating the die and the framing structure; and a redistribution layer (RDL) on the die, on the framing structure, and on the encapsulant, wherein the RDL is electrically connected to the die. In one embodiment, the framing structure has a coefficient of thermal expansion (CTE) that substantially matches a CTE of the die.

In another embodiment, the die of the semiconductor device is silicon. In some embodiments, the framing structure has a coefficient of thermal expansion (CTE) that substantially matches the CTE of silicon. In other embodiments, the framing structure is glass. In some examples, the RDL includes at least a dielectric layer and metal features in the dielectric layer.

In one embodiment, the method of manufacturing a semiconductor device includes providing a framing member having a framing structure that define a plurality of through-holes through the framing member, followed by adhering the framing member to a supporting surface of a carrier substrate, and then adhering a plurality of dies to the supporting surface of the carrier substrate within respective through-holes of the framing member, where each die has a respective active surface and at least one respective integrated circuit region. In an alternative embodiment, the two adhering steps can be carried out in reverse.

In one embodiment, the next step of the method of manufacturing the semiconductor device includes encapsulating the framing member and the plurality of dies within an encapsulant, thereby resulting in a multi-die encapsulated layer, followed by removing the carrier substrate from the multi-die encapsulated layer. The process further continues with forming a redistribution layer (RDL) on the dies of the multi-die encapsulated layer, thereby resulting in a multi-die panel. In another embodiment, the multi-die panel may be further subjected to a dicing step whereby the multi-layer panel can be singulated along the plurality of framing structures to obtain separate semiconductor devices.

In some embodiments, the carrier substrate may have a coefficient of thermal expansion (CTE) that substantially matches a CTE of the plurality of dies. Likewise, the framing member has a coefficient of thermal expansion (CTE) that substantially matches a CTE of the plurality of dies and/or the carrier substrate.

In some embodiments, a first framing structure of the plurality of framing structures can extend along the supporting surface of the carrier substrate between a first die and a second die of the plurality of dies. In other embodiments, the dicing of the multi-layer panel includes dicing the multi-layer panel along the first framing structure such that at least a first portion of the first framing structure remains adjacent to the first die and at least a second portion of the first framing structure remains adjacent to the second die.

In one embodiment, each of the plurality of dies includes silicon. In another embodiment, the framing member has a coefficient of thermal expansion (CTE) that substantially matches the CTE of silicon.

In one embodiment, a method of manufacturing a semiconductor device includes: adhering a framing member to a supporting surface of a carrier substrate, where the framing member defines first and second through-holes through the framing member, and where the framing member comprises a framing structure that interposes the first and second through-holes; adhering first and second dies to the supporting surface of the carrier substrate within the respective first and second through-holes of the framing member, where each of the first and second dies has a respective active surface and at least one respective integrated circuit region; encapsulating the framing member and the first and second dies within an encapsulant, thereby resulting in a multi-die encapsulated layer; removing the carrier substrate from the multi-die encapsulated layer; forming a redistribution layer (RDL) on the first and second dies of the multi-die encapsulated layer, thereby resulting in a multi-die panel; and dicing the multi-layer panel along the framing structure to obtain first and second semiconductor devices.

In one embodiment, the carrier substrate has a coefficient of thermal expansion (CTE) that substantially matches a CTE of the first and second dies. In another embodiment, the framing member has a coefficient of thermal expansion (CTE) that substantially matches a CTE of the first and second dies, and/or that of the carrier substrate.

In one embodiment, the framing structure extends along the supporting surface of the carrier substrate between the first die and the second die. In some embodiments, the dicing of the multi-layer panel includes dicing the multi-layer panel along the framing structure such that at least a first portion of the first framing structure remains adjacent to the first die and at least a second portion of the first framing structure remains adjacent to the second die.

In one embodiment, each of the first and second dies includes silicon. In another embodiment, the framing member has a coefficient of thermal expansion (CTE) that substantially matches the CTE of silicon.

### BRIEF DESCRIPTION OF THE DRAWINGS

FIG. 1 shows a schematic, cross-sectional diagram of a typical FOWLP wafer level package.

FIGS. 2A-2E show schematic, cross-sectional diagrams of an exemplary method for fabricating a semiconductor device according to embodiments of the present disclosure.

FIGS. 3A-3B show plan and cross-sectional views, respectively, of a framing member according to an embodiment of the present disclosure.

FIGS. 4A-4B show plan and cross-sectional views, respectively, of a framing member and carrier substrate according to an embodiment of the present disclosure.

FIG. 5 is a process flow diagram showing an exemplary method of fabricating a semiconductor device according to the present disclosure.

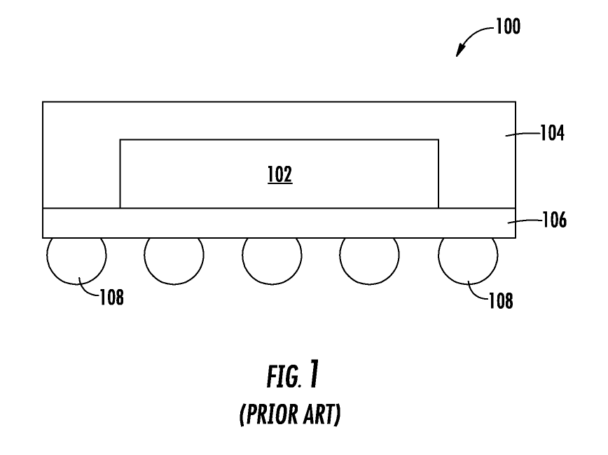

### DETAILED DESCRIPTION

This disclosure relates to a wafer level packaging process. For example, in semiconductor wafer packaging processes, the wafer can be a semiconductor wafer or device wafer which has thousands of chips on it. Thin wafers, especially ultra-thin wafers (thickness less than 60 microns or even 30 microns) are very unstable, and more susceptible to stress than traditional thick wafers. During processing, thin wafers and dies may be easily broken and warped. Therefore, temporary bonding to a rigid support carrier substrate can reduce the risk of damage to the wafer. A carrier substrate, may be square or rectangular shaped panels made of glass, sapphire, metal, or other rigid materials to increase chips volumes. In one die packaging method, dies are placed temporarily on temporary adhesive coated carrier substrate, are encapsulated within an encapsulant material, such as an epoxy molding compound. The encapsulated dies are then processed with desired semiconductor packaging operations including RDL formation and dicing into individual chips.

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present invention.

The following detailed description is, therefore, not to be taken in a limiting sense, and the scope of the present invention is defined only by the appended claims, along with the full scope of equivalents to which such claims are entitled.

One or more implementations of the present invention will now be described with reference to the attached drawings, wherein like reference numerals are used to refer to like elements throughout, and wherein the illustrated structures are not necessarily drawn to scale.

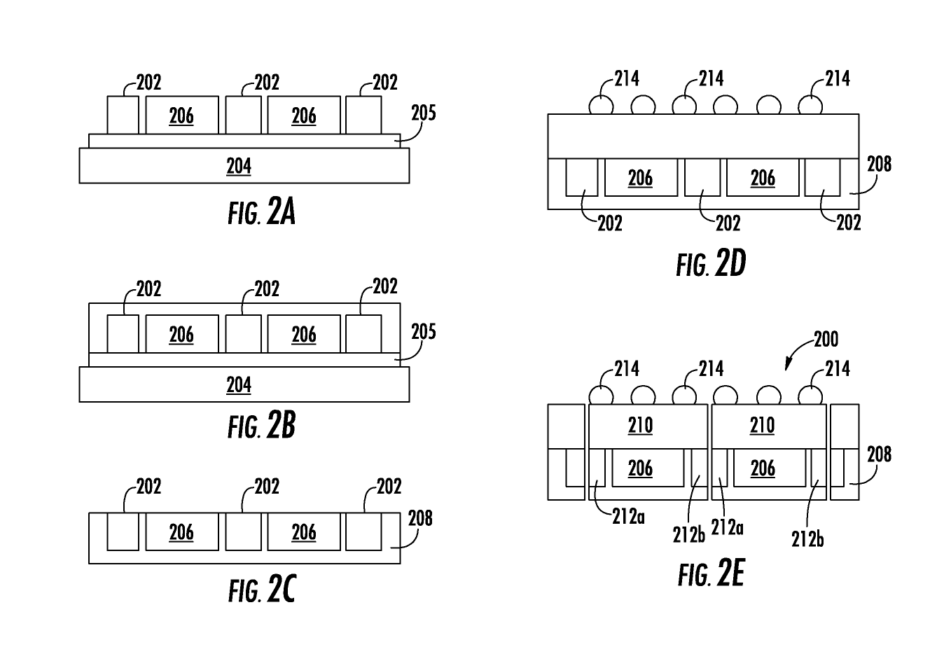

FIGS. 2A-2E show schematic, cross-sectional diagrams showing an exemplary method for fabricating a semiconductor device according to the present disclosure.

As shown in FIG. 2A, a carrier substrate 204 is prepared. The carrier substrate 204 may include a releasable substrate material. An adhesive layer 205 is disposed on a top surface of the carrier substrate 204. In one embodiment, the carrier substrate 204 may be a glass substrate, but may alternatively be any other material having a CTE that is matched to that of the dies 206 being processed. For example, the carrier substrate 204 may also be ceramic, sapphire or quartz. The adhesive layer 205 may be adhesive tape, or alternatively, may be a glue or epoxy applied to the carrier substrate 204 via a spin-on process, or the like.

Subsequently, semiconductor dies 206 and a framing member 202 may be mounted on a supporting surface of the carrier substrate 204 via the adhesive layer 205. The order of assembly can vary; in other words, the framing member 202 may be placed before, during, or after placement of the dies 206. Also, while two dies 206 and through-holes are shown, alternative embodiments can include any number of dies 206 and through-holes.

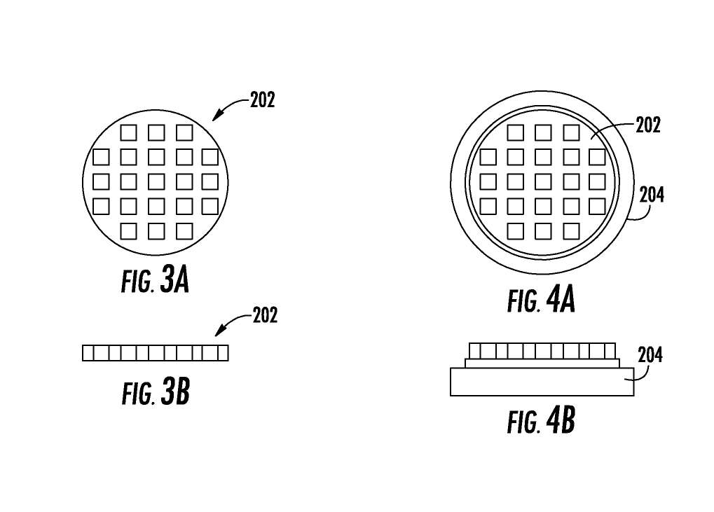

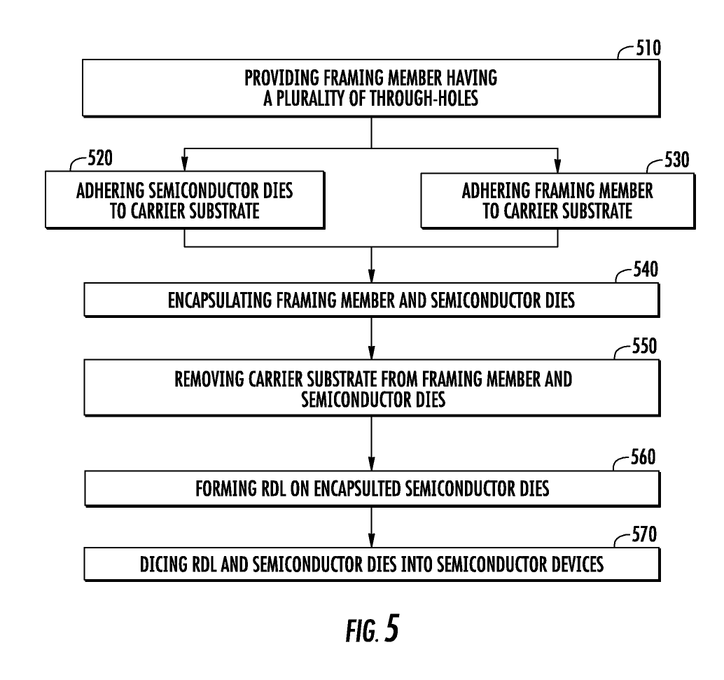

For example, FIGS. 3A and 3B respectively show a plan view and cross-sectional view of an exemplary framing member 202, and FIGS. 4A and 4B respectively show a plan view and cross-sectional view of an exemplary framing member 202 mounted on a carrier substrate 204. As illustrated, the framing member 202 defines a plurality of through-holes that are sized and shaped to allow for respective dies 206 to be positioned therein as shown in FIGS. 2A-2E. In some embodiments, the framing member 202 also be referred to as a stiffener material. In other embodiments, the framing member 202 may be formed of glass, ceramic, sapphire, quartz, or other suitable material having a CTE at least substantially matching that of the carrier substrate 204 and/or the semiconductor dies 206.

In some embodiments, the plurality of through-holes may be of the same size as the respective dies 206 or be slightly larger than the dimensions of the respective dies 206. Also, while the framing member 202 is illustrated as being circular in the plan views shown in FIGS. 3A and 4A, alternative embodiments of the framing member 202 can have any desired shape, such as square or rectangular. Likewise, although the carrier substrate 204 is shown to be circular it, too, can have any desired shape such as square or rectangular. The dies 206 and framing member 202 may be mounted on the carrier substrate 204 by using any conventional surface mount technique, but not limited thereto.

In some embodiments, the thickness of the carrier substrate 204 may be the same as that of the respective dies 206. In other words, the thickness of the glass substrate 204 may be the same as the thickness of the semiconductor dies 206.

As shown in FIG. 2B, after the dies 206 and framing member 202 are mounted on the carrier substrate 204, an encapsulant, such as molding compound 208, is applied. The molding compound 208 covers the attached dies 206 and framing member 202. The molding compound 208 can also fill any gaps that may exist between the dies 206 and the framing member 202. The molding compound 208 may then be subjected to a curing process.

According to the illustrated embodiment, the molding compound 208 may be formed using thermoset molding compounds in a transfer mold press, for example. Other means of dispensing the molding compound may be used. Epoxies, resins, and compounds that are liquid at elevated temperature or liquid at ambient temperatures may be used. The molding compound 208 can be an electrical insulator, and can be a thermal conductor. Different fillers may be added to enhance the thermal conduction, stiffness or adhesion properties of the molding compound 208.

Turning next to FIGS. 2C-2E, note that the illustrated structure is flipped over such that the top side as shown in FIGS. 2A-2B is the bottom side as shown in FIGS. 2C-2E. As shown in FIG. 2C, after the formation of the molding compound 208, the carrier substrate 204 and the adhesive layer 205 are removed or peeled off to expose the dies 206 and framing member 202. The removal process can be carried via known techniques.

As shown in FIG. 2D, subsequently, an RDL 210 may be fabricated using known RDL formation techniques. Also, to provide electrical connection between the RDL 210 and other circuitry, a plurality of bumps 214 such as micro-bumps or copper pillars are formed. Optionally, a thermal process may be performed to reflow the bumps 214.

As shown in FIG. 2E, a dicing or sawing process may be performed along kerf regions to separate individual dies 206 into respective semiconductor devices 200. Notably, after the dicing process, the individual semiconductor devices 200 include portions 212a and 212b of the framing structure adjacent to the die 206. The portions 212 of the framing structure that remain after dicing will preferably surround the die 206. As a result, the framing portions 212 act as a stiffener to enhance the mechanical strength of the device 200. The CTE of the framing portions 212 can be closely matched to that of the die 206, thus significantly reducing warpage. It is understood that the sectional structures depicted in the figures are for illustration purposes only.

In one embodiment, individual semiconductor devices 206 with the packaging structure as that shown in FIG. 2E can be produced by the processing steps described above. In this embodiment, the semiconductor device 200 includes a die 206 having an active surface and at least one integrated circuit region; a framing structure 212a, 212b adjacent to the die; an encapsulant 208 at least partially encapsulating the die and the framing structure; and a redistribution layer (RDL) 210 on the die, on the framing structure, and on the encapsulant, wherein the RDL is electrically connected to the die. In one embodiment, the framing structure has a coefficient of thermal expansion (CTE) that substantially matches a CTE of the die and/or the carrier substrate.

In another embodiment, the die of the semiconductor device 200 is silicon. In some embodiments, the framing structure has a coefficient of thermal expansion (CTE) that substantially matches the CTE of silicon. In other embodiments, the framing structure is glass. In some examples, the RDL includes at least a dielectric layer and metal features in the dielectric layer.

FIG. 5 is a process flow diagram showing an exemplary method of fabricating a semiconductor device according to the present disclosure. In this embodiment, the method of manufacturing a semiconductor device starts with a step 510 of providing a framing member having a framing structure that define a plurality of through-holes through the framing member. In one embodiment, the next step 530 involves adhering the framing member to a supporting surface of a carrier substrate. In another embodiment, the next step 520 involves adhering a plurality of dies to the supporting surface of the carrier substrate within respective through-holes of the framing member, where each die has a respective active surface and at least one respective integrated circuit region. In an alternative embodiment, steps 520 and 530 may be carried out in reverse order, e.g., step 520 followed by step 530. Next step 530 involves encapsulating the framing member and the plurality of dies within an encapsulant, thereby resulting in a multi-die encapsulated layer, followed by the processing step 550 of removing the carrier substrate from the multi-die encapsulated layer. The next step 560 of the process includes forming a redistribution layer (RDL) on the dies of the multi-die encapsulated layer, thereby resulting in a multi-die panel. In one embodiment, the multi-die panel may be further subjected to a dicing step 570 whereby the multi-layer panel can be singulated along the plurality of framing structures to obtain separate semiconductor devices.

In some embodiments, in the methods discussed above, the carrier substrate may have a coefficient of thermal expansion (CTE) that substantially matches a CTE of the plurality of dies. Likewise, the framing member has a coefficient of thermal expansion (CTE) that substantially matches a CTE of the plurality of dies and/or the carrier substrate.

For example, the encapsulation molding compound may have a CTE of greater than about 7 ppm/K, while the semiconductor silicon die may have a CTE of about 3 ppm/K. This discrepancy may result in induced warpage during traditional FOWLP processing, and also subsequent processing challenges including subsequent surface mounting to printed circuit boards (PCB's). The framing member, e.g., glass, can have a CTE in the range of from about 2 to about 10 ppm/K. Accordingly, the framing member can be materially matched to that of the silicon substrate to reduce warpage, improve process yield, and lower product cost.

In some embodiments, a first framing structure of the plurality of framing structures can extend along the supporting surface of the carrier substrate between a first die and a second die of the plurality of dies. In other embodiments, the dicing of the multi-layer panel includes dicing the multi-layer panel along the first framing structure such that at least a first portion of the first framing structure remains adjacent to the first die and at least a second portion of the first framing structure remains adjacent to the second die.

In one embodiment, each of the plurality of dies includes silicon. In another embodiment, the framing member has a coefficient of thermal expansion (CTE) that substantially matches the CTE of silicon.

In one embodiment, a method of manufacturing a semiconductor device includes: adhering a framing member to a supporting surface of a carrier substrate, where the framing member defines first and second through-holes through the framing member, and where the framing member comprises a framing structure that interposes the first and second through-holes; adhering first and second dies to the supporting surface of the carrier substrate within the respective first and second through-holes of the framing member, where each of the first and second dies has a respective active surface and at least one respective integrated circuit region; encapsulating the framing member and the first and second dies within an encapsulant, thereby resulting in a multi-die encapsulated layer; removing the carrier substrate from the multi-die encapsulated layer; forming a redistribution layer (RDL) on the first and second dies of the multi-die encapsulated layer, thereby resulting in a multi-die panel; and dicing the multi-layer panel along the framing structure to obtain first and second semiconductor devices.

In one embodiment, the carrier substrate has a coefficient of thermal expansion (CTE) that substantially matches a CTE of the first and second dies. In another embodiment, the framing member has a coefficient of thermal expansion (CTE) that substantially matches a CTE of the first and second dies, and/or that of the carrier substrate.

In one embodiment, the framing structure extends along the supporting surface of the carrier substrate between the first die and the second die. In some embodiments, the dicing of the multi-layer panel includes dicing the multi-layer panel along the framing structure such that at least a first portion of the first framing structure remains adjacent to the first die and at least a second portion of the first framing structure remains adjacent to the second die.

In one embodiment, each of the first and second dies includes silicon. In another embodiment, the framing member has a coefficient of thermal expansion (CTE) that substantially matches the CTE of silicon.

In operation, the currently disclosed embodiments are able to produce larger semiconductor package sizes than those with traditional methods. For example, the currently disclosed embodiments are able to deliver package sizes that are greater than about 5×5 square millimeters packages, or greater than about 6×6 square millimeters packages, or greater than about 7×7 square millimeters packages, or greater than about 8×8 square millimeters packages. In other embodiments, the packages can be rectangular (e.g., greater than 5×8 square millimeters packages or greater than 6×8 square millimeters packages) or other polygonal shaped packages.

Those skilled in the art will readily observe that numerous modifications and alterations of the device and method may be made while retaining the teachings of the invention. Accordingly, the above disclosure should be construed as limited only by the metes and bounds of the appended claims.

1. A method of manufacturing a semiconductor device, comprising:
adhering a framing member to a supporting surface of a carrier substrate, wherein the framing member comprises a plurality of framing structures that define a plurality of through-holes through the framing member;
adhering a plurality of dies to the supporting surface of the carrier substrate within respective through-holes of the framing member, wherein each die has a respective active surface and at least one respective integrated circuit region;
encapsulating the framing member and the plurality of dies within an encapsulant, thereby resulting in a multi-die encapsulated layer;
removing the carrier substrate from the multi-die encapsulated layer;
forming a redistribution layer (RDL) on the dies of the multi-die encapsulated layer, thereby resulting in a multi-die panel; and
dicing the multi-die panel along the plurality of framing structures to obtain separate semiconductor devices.

2. The method of claim 1, wherein the carrier substrate has a coefficient of thermal expansion (CTE) that substantially matches a CTE of the plurality of dies.

3. The method of claim 1, wherein the framing member has a coefficient of thermal expansion (CTE) that substantially matches a CTE of the plurality of dies.

4. The method of claim 1, wherein a first framing structure of the plurality of framing structures extends along the supporting surface of the carrier substrate between a first die and a second die of the plurality of dies.

5. The method of claim 4, wherein the dicing of the multi-die panel includes dicing the multi-die panel along the first framing structure such that at least a first portion of the first framing structure remains adjacent to the first die and at least a second portion of the first framing structure remains adjacent to the second die.

6. The method of claim 1, wherein each of the plurality of dies comprises silicon.

7. The method of claim 6, wherein the framing member has a coefficient of thermal expansion (CTE) that substantially matches the CTE of silicon.

8. A method of manufacturing a semiconductor device, comprising:
adhering a framing member to a supporting surface of a carrier substrate, wherein the framing member defines first and second through-holes through the framing member, and wherein the framing member comprises a framing structure that interposes the first and second through-holes;
adhering first and second dies to the supporting surface of the carrier substrate within the respective first and second through-holes of the framing member, wherein each of the first and second dies has a respective active surface and at least one respective integrated circuit region;
encapsulating the framing member and the first and second dies within an encapsulant, thereby resulting in a multi-die encapsulated layer;
removing the carrier substrate from the multi-die encapsulated layer;
forming a redistribution layer (RDL) on the first and second dies of the multi-die encapsulated layer, thereby resulting in a multi-die panel; and
dicing the multi-die panel along the framing structure to obtain first and second semiconductor devices.

9. The method of claim 8, wherein the carrier substrate has a coefficient of thermal expansion (CTE) that substantially matches a CTE of the first and second dies.

10. The method of claim 8, wherein the framing member has a coefficient of thermal expansion (CTE) that substantially matches a CTE of the first and second dies.

11. The method of claim 8, wherein the framing structure extends along the supporting surface of the carrier substrate between the first die and the second die.

12. The method of claim 8, wherein the dicing of the multi-die panel includes dicing the multi-die panel along the framing structure such that at least a first portion of the framing structure remains adjacent to the first die and at least a second portion of the framing structure remains adjacent to the second die.

13. The method of claim 8, wherein each of the first and second dies comprises silicon.

14. The method of claim 13, wherein the framing member has a coefficient of thermal expansion (CTE) that substantially matches the CTE of silicon.

15. A semiconductor device, comprising:
a die comprising an active surface and at least one integrated circuit region;
a framing structure adjacent to the die;
an encapsulant at least partially encapsulating the die and the framing structure; and
a redistribution layer (RDL) on the die, on the framing structure, and on the encapsulant, wherein the RDL is electrically connected to the die.

16. The semiconductor device of claim 15, wherein the framing structure has a coefficient of thermal expansion (CTE) that substantially matches a CTE of the die.

17. The semiconductor device of claim 15, wherein the die comprises silicon.

18. The semiconductor device of claim 17, wherein the framing structure has a coefficient of thermal expansion (CTE) that substantially matches the CTE of silicon.

19. The semiconductor device of claim 18, wherein the framing structure comprises glass.

20. The semiconductor device of claim 15, wherein the RDL comprises at least a dielectric layer and metal features in the dielectric layer.
